(19) United States
(12) Patent Application Publication
(10) Pub. No.: US 2021/0249629 A1
(43) Pub. Date: Aug. 12, 2021

(54) FOLDABLE DISPLAY DEVICE

(71) Applicant: InnoLux Corporation, Miao-Li County (TW)

(72) Inventor: Yuan-Lin Wu, Miao-Li County (TW)

(21) Appl. No.: 17/239,703

(22) Filed: Apr. 26, 2021

Related U.S. Application Data
(63) Continuation of application No. 15/895,955, filed on Feb. 13, 2018.

(51) Int. Cl. H01L 51/52; H01L 51/00; H01L 27/32

(52) U.S. Cl. CPC H01L 51/5253; G02B 5/30; H01L 27/3244; H01L 51/0097

(57) ABSTRACT

A foldable display device includes a substrate including a foldable portion, a display structure disposed on the foldable portion and having a plurality of display units, and an encapsulation layer, a touch layer, and a protecting layer having a first top surface disposed on the display structure in order. The foldable portion has a plurality of recesses and a first bottom surface at one of the recesses. The display structure has a second bottom surface. At least a portion of the touch layer and one of the display units adjacent to the portion of the touch layer are not overlapped in a thickness direction. A first distance is measured from the first bottom surface to the first top surface, a second distance is measured from the first bottom surface to the second bottom surface, and a ratio of the second distance to the first distance ranges from 0.3 to 0.5.

### CROSS REFERENCE TO RELATED APPLICATIONS

This application is a continuation application of U.S. application Ser. No. 15/895,955, filed on Feb. 13, 2018.

### BACKGROUND OF THE DISCLOSURE

### 1. Field of the Disclosure

The present disclosure relates to a display device, and more particularly, to a foldable display device.

### 2. Description of the Prior Art

In recent years, foldable electronic devices have become one of the focuses of the new generation electronic technology. The demand of the foldable display device that can be integrated in the foldable electronic device is therefore increased. A foldable display device means the device can be curved, folded, stretched, flexed, or the like. However, some elements or films in the folding part of the conventional display device may be damaged due to the stress induced by folding or flexing state of the display device, such as the electrodes, the active layer of thin film transistors (TFTs), and the signal lines, which influences the light emitting quality and the properties of the TFT. Thus, the stability and the reliability of the foldable display device are seriously affected.

### SUMMARY OF THE DISCLOSURE

In one embodiment, the present disclosure provides a foldable display device that includes a substrate, a display structure, and a protecting layer.

The substrate includes a foldable portion, and the foldable portion has a first bottom surface. The display structure is disposed on the foldable portion and has a second bottom surface. The protecting layer is disposed on the foldable portion and on the display structure. The protecting layer has a first top surface. A first distance is measured from the first bottom surface to the first top surface, a second distance is measured from the first bottom surface to the second bottom surface, and a ratio of the second distance to the first distance is in a range from 0.3 to 0.5.

In another embodiment, the present disclosure provides a foldable display device includes a substrate, a display structure, an encapsulation layer, a touch layer, and a protecting layer. The substrate includes a foldable portion, wherein the foldable portion has a plurality of recesses, and the foldable portion has a first bottom surface at one of the recesses. The display structure is disposed on the foldable portion and has a second bottom surface, wherein the display structure has a plurality of display units. The encapsulation layer is disposed on the display structure. The touch layer is disposed on the encapsulation layer, wherein the encapsulation layer is disposed between the display structure and the touch layer, and at least a portion of the touch layer and one of the display units adjacent to the at least a portion of the touch layer are not overlapped in a thickness direction. The protecting layer is disposed on the foldable portion and on the touch layer, wherein the protecting layer having a first top surface. A first distance is measured from the first bottom surface to the first top surface, a second distance is measured from the first bottom surface to the second bottom surface, and a ratio of the second distance to the first distance is in a range from 0.3 to 0.5.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of a top view of a foldable display device according to a first embodiment of the present disclosure.

FIG. 2 is a schematic diagram of a side view of the foldable display device shown in FIG. 1.

FIG. 3 is a partial-enlargement schematic diagram illustrating a cross-section of the foldable display device shown in FIG. 1.

FIG. 4 is a schematic diagram illustrating the probability of damage versus different values of the first ratio of the foldable display device.

FIG. 5 is a schematic diagram illustrating the probability of damage versus different values of the second ratio of the foldable display device.

FIG. 6 is a schematic diagram illustrating the probability of damage versus different values of the third ratio of the foldable display device.

FIG. 7 is a partial-enlargement schematic diagram illustrating a cross-section of a foldable display device according to a second embodiment of the present disclosure.

FIG. 8 is a schematic diagram illustrating the probability of damage versus different values of the fourth ratio of the foldable display device.

FIG. 9 is a partial enlargement schematic diagram illustrating a cross-section of a foldable display device according to a variant embodiment of the second embodiment of the present disclosure.

FIG. 10 is a partial-enlargement schematic diagram illustrating a cross-section of a foldable display device according to a third embodiment of the present disclosure

FIG. 11 is a partial-enlargement schematic diagram illustration a cross-section of the foldable display device according to a fourth embodiment of the present disclosure.

FIG. 12 is a partial-enlargement schematic diagram illustration a cross-section of the foldable display device according to a fifth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the display device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”.

It will be understood that when an element or layer is referred to as being “on” or “connected to” another element or layer, it can be directly on or directly connected to the other element or layer, or intervening elements or layers may be presented. In contrast, when an element is referred to as being “directly on” or “directly connected to” another element or layer, there are no intervening elements or layers presented.

It should be noted that the technical features in different embodiments described in the following can be replaced, recombined, or mixed with one another to constitute another embodiment without departing from the spirit of the present disclosure.

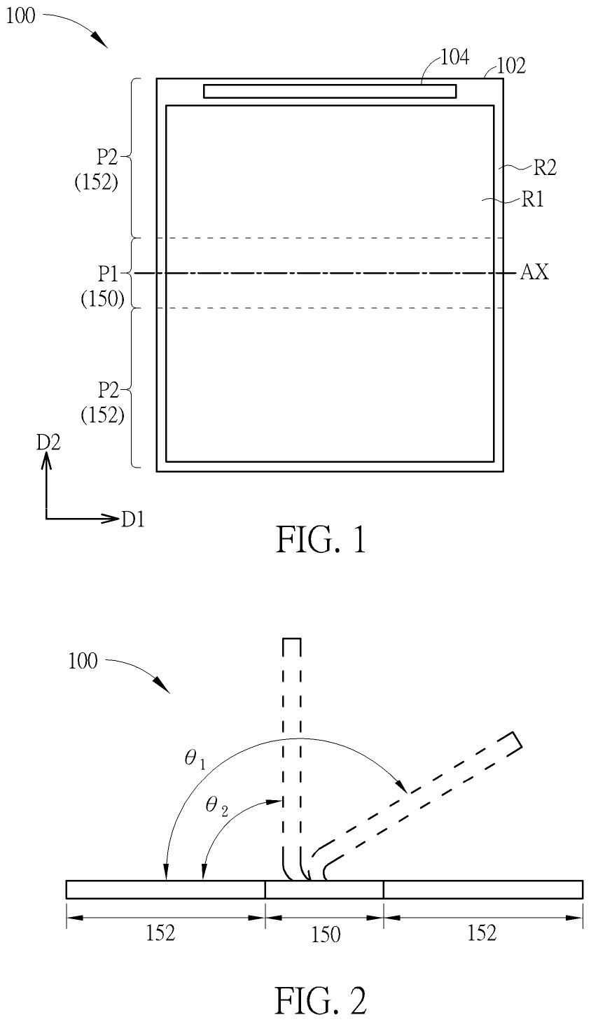

Referring to FIG. 1 and FIG. 2, FIG. 1 is a schematic diagram of a top view of a foldable display device according to a first embodiment of the present disclosure, and FIG. 2 is a schematic diagram of a side view of the foldable display device shown in FIG. 1. A foldable display device 100 of this embodiment shown in FIG. 1 and FIG. 2 includes a substrate 102 that has a foldable portion P1. The foldable portion P1 of the substrate 102 can be repeatedly folded. The terms “folded” in the present disclosure means curved, bended, folded, rolled, stretched, flexed, or the like (generally referred to as “folded” or “foldable” hereinafter) along at least one folding axis AX, which is in parallel with the first direction D1. Accordingly, the foldable display device 100 has a foldable region 150 corresponding to the foldable portion P1 of the substrate 102. In the same way, the foldable display device 100 can be repeatedly folded at the foldable region 150. The substrate 102 may further include a main portion P2 adjoining to the foldable portion P1. Similarly, the foldable display device 100 has a main region 152 corresponding to the main portion P2 of the substrate 102. In this embodiment, the foldable display device 100 includes two main portions P2 for instance, and the foldable portion P1 is disposed adjacent to and between the two main portions P2 in a second direction D2. The first direction D1 and the second direction D2 can be perpendicular.

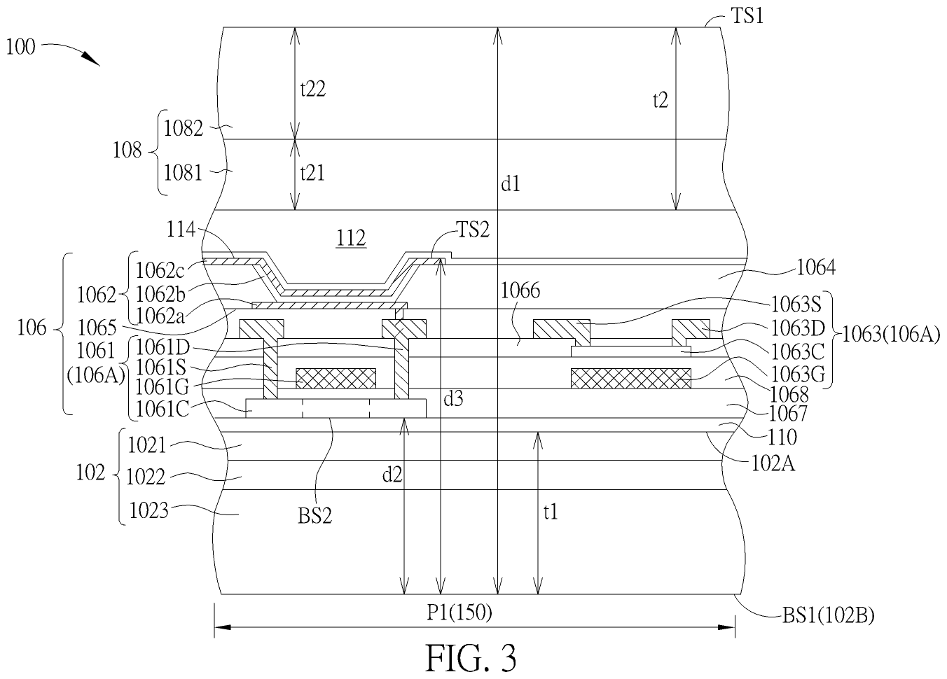

In addition, a display region R1 and a peripheral region R2 are defined on the substrate 102. A display structure 106 (shown in FIG. 3 and will be described in details below) is disposed in the display region R1 and on a front surface 102A of the substrate 102. The peripheral region R2 can surround the display region R1, and a plurality of peripheral wires and elements may be disposed in the peripheral region R2. For example, one or more integrated circuits 104 may be disposed in the peripheral region R2 in this embodiment. Alternatively, one or more integrated circuits (ICs) 104 can be bent to a rear surface 102B of the substrate 102, so that ICs do not occupy the front surface 102A of the substrate 102, thus reducing the area of peripheral region R2.

As shown in FIG. 2, the foldable display device 100 may be folded inwardly or outwardly by various folding angles. For example, the folding angle θ₁ is 150 degrees and the folding angle θ₂ is 90 degrees. According to this embodiment, the folding angle may range from 0 degrees to 180 degrees when the foldable display device 100 is folded inwardly, and the folding angle may range from 0 degree to −180 degrees when the foldable display device 100 is folded outwardly, but not limited thereto. When the folding angle is 180 degrees or −180 degrees, the two main portions P2 may substantially face to each other. The foldable display device 100 of FIG. 2 shows one foldable portion P1. Alternatively, in some embodiments, the foldable display device can include more than one foldable portion. For example, the display device can include one inward foldable portion and one outward foldable portion.

Referring to FIG. 3, FIG. 3 is a partial-enlargement schematic diagram illustrating a cross-section of the foldable portion of the display device shown in FIG. 1. The substrate 102 may include a flexible substrate 1021 and a supporting film 1023, and the flexible substrate 1021 can be adhered to the supporting film 1023 through a glue 1022. The foldable portion P1 of the substrate 102 (or the substrate 102 itself) may include any material that is flexible. For example, the substrate 102 may include polymer material, thin glass, or any suitable material. In some embodiments, the substrate 102 itself may be a polymeric substrate or a polymer layer, or the substrate 102 may include a polymer layer. As an example, the supporting film 1023 is a polyethylene terephthalate (PET) substrate, a polyimide (PI) substrate, or a polyethylene naphthalate (PEN) substrate, but not limited thereto.

The foldable display device 100 further includes a display structure 106 and a protecting layer 108 at least disposed on the foldable portion P1 of the substrate 102 from bottom to top sequentially. In other words, the display structure 106 and the protecting layer 108 are at least disposed in the foldable region 150 of the foldable display device 100. In this embodiment, the display structure 106 and the protecting layer 108 can also be disposed on the main portions P2 of the substrate 102.

Referring to FIGS. 1 to 3, the display structure 106 can be disposed in the display region R1 and on the front surface 102A of the substrate 102. The display structure 106 can be disposed both in the foldable region 150 and in the main region 152. The display structure 106 can include a plurality of display units and a plurality of circuit portions. The plurality of circuit portions can be arranged in an array. For example, the circuit portions can have the same repeating structures arranged in an array. Each circuit portion 106A of the plurality of circuit portions is correspondingly to drive each display unit 1062 of the plurality of display units. Specifically, FIG. 3 shows a portion of the display structure 106 in the foldable region 150. The display structure 106 includes a display unit 1062 and a circuit portion 106A to drive the display unit 1062. The circuit portion 106A can include a driving element 1061 (shown as a driving TFT). In addition, the circuit portion 106A can include a switch element 1063 (shown as a switch TFT).

Still referring to FIG. 3, in the circuit portion 106A, the driving element 1061 is directly electrically connected to, for example, the display unit 1062. In details, a drain electrode 1061D of the driving element 1061 is electrically connected to an electrode 1062a of the display unit 1062. FIG. 3 shows that the driving element 1061 and the display unit 1062 overlap along a thickness direction. However, FIG. 3 is shown for illustration only. It should be noted that in other embodiments, the driving element 1061 and the display unit 1062 can be disposed in the position not overlapping along the thickness direction.

The display unit 1062 may be any type of display units or cells, such as an organic light-emitting diode (OLED), a micro light-emitting diode (micro-LED), a mini-LED, or quantum dot LED (QLED), but not limited thereto. In this embodiment, the display unit 1062 may be an OLED as an example. As shown in FIG. 3, the display unit 1062 includes a first electrode 1062a, a second electrode 1062c and an organic light-emitting layer 1062b disposed between the first electrode 1062a and the second electrode 1062c. The first electrode 1062a may be an anode and the second electrode 1062c may be a cathode of the display unit 1062 in this embodiment for example, but not limited thereto. The display area of the display unit 1062 is defined by a dielectric layer 1064, wherein the dielectric layer 1064 may serve as a pixel defining layer (PDL).

The organic light-emitting layer 1062b may include one or more layers of organic emissive material. In the plurality of display units, all the display units 1062 can emit light of the same color. Or, alternatively, different display units 1062 can emit lights of different colors, such as red, green and blue colors. For example, the organic light-emitting layers in different display units 1062 can be made of different materials emitting light of red, green, and blue.

The first electrode 1062a and the second electrode 1062c may include metal or transparent conductive material respectively. Examples of the metal material of the electrodes include Mg, Ca, Al, Ag, W, Cu, Ni, Cr, or an alloy thereof. Examples of the transparent conductive material include indium tin oxide (ITO), indium zinc oxide (IZO), zinc oxide, or indium oxide. In this embodiment, the first electrodes 1062a are made of metal material, and the second electrodes 1062c are made of transparent conductive material, but not limited thereto. In other embodiments, the first electrodes 1062a are made of transparent conductive material, and the second electrodes 1062c are made of metal.

The driving element 1061 may be a thin film transistor (TFT) in this embodiment, which is a top-gate type TFT, but not limited thereto. Thus, the driving element 1061 includes a semiconductor layer 1061C, a dielectric layer 1067, a gate electrode 1061G, a dielectric layer 1068, a drain electrode 1061D and a source electrode 1061S. The semiconductor layer 1061C is formed of a semiconductor material, such as silicon or metal oxide, but not limited thereto. For example, the semiconductor layer 1061C may be amorphous silicon, polysilicon, or indium gallium zinc oxide (IGZO). Furthermore, the semiconductor layer 1061C includes a source contact, a drain contact, and a channel disposed between the source contact and the drain contact in one driving element 1061. The source electrode 1061S is electrically connected to the corresponding source contact through a via hole in the dielectric layer 1067 and the dielectric layer 1068. The drain electrode 1061D is electrically connected to the corresponding drain contact through another via hole in the dielectric layer 1067 and the dielectric layer 1068. The gate electrode 1061G is separated from the semiconductor layer 1061C by the dielectric layer 1067, which serves as the gate insulating layer of the driving element 1061. The gate electrode 1061G, the source electrode 1061S, and the drain electrode 1061D are formed of conductive materials (such as metal), but not limited thereto. Suitable material for the gate electrode 1061G, the source electrode 1061S, and the drain electrode 1061D can be the material mentioned above for the first electrode 1062a and the second electrode 1062c. In the present disclosure, the driving element 1061 is directly connected to the display unit 1062 through the drain electrode 1061D for driving the display unit 1062. In detail, the drain electrode 1061D may be directly connected to the first electrode 1062a of the display unit 1062. In addition, a dielectric layer 1065 is disposed between the first electrode 1062a of the display unit 1062 and the conductive layer forming the source electrode 1061S and the drain electrode 1061D.

Furthermore, in addition to the driving element 1061 and the switch element 1063 mentioned above, the circuit portion 106A can further include one or more electronic elements, such as, but not limited to, other TFT(s), a reset element, a compensation element, an initialization element, an operation control element, a light emission control element, a capacitor, or combinations thereof. In this embodiment, the switch element 1063 may have a bottom-gate type of TFT structure for instance. The switch element 1063 includes a gate electrode 1063G, a semiconductor layer 1063C, the dielectric layer 1068 serving as the gate insulating layer, a dielectric layer 1066, a drain electrode 1063D, and a source electrode 1063S. The material forming the semiconductor layer 1063C may refer to the above-mentioned material of the semiconductor layer 1061C of the driving element 1061. The material(s) forming the drain electrode 1063D, the source electrode 1063S, and the gate electrode 1063G may include metal material (s), which may refer to the materials mentioned for the first electrode 1062a and the second electrode 1062c of the display unit 1062, but not limited thereto. Redundant description will not be repeated.

Although the driving element 1061 has a top-gate type of TFT structure and the switch element 1063 has a bottom-gate type of TFT structure, it is merely an example of the present disclosure and is not meant to limit the types or structures of the TFTs of the display structure 106 of the present disclosure. Any other suitable TFT structures and combinations may replace the illustrated driving element 1061 and switch element 1063. For example, the driving element 1061 may have a bottom-gate TFT structure while the switch element 1063 may have a top-gate TFT structure in one variant embodiment. In another variant embodiment, the driving element 1061 and the switch device 1063 may both have top-gate TFT structures or both have bottom-gate TFT structures.

In addition, a buffer layer 110 may be selectively disposed on the substrate 102, and the display structure 106 is disposed on the buffer layer 110. In other words, the buffer layer 110 is disposed between the flexible substrate 1021 and the display structure 106. In this embodiment, the buffer layer 110 may include an oxide layer, a nitride layer or other suitable insulating layer, but not limited thereto. Furthermore, an insulating layer 114 and an encapsulation layer 112 may be selectively disposed on the display structure 106. The insulating layer 114 may conformally cover the display structure 106 and include inorganic material, such as oxide or nitride, but not limited thereto. The encapsulation layer 112 may provide protection, encapsulation and planarization function for the display structure 106 and may include organic material, but not limited thereto.

The protecting layer 108 is disposed on the display structure 106 and covers the display structure 106 therebelow. In detail, the protecting layer 108 may include a polarizer 1081 and a cover layer 1082 in this embodiment. The polarizer 1081 may include polyvinyl alcohol (PVA) material or any other suitable material. The cover layer 1082 may include organic or inorganic materials, such as the materials mentioned above for the supporting film 1023, but not limited thereto.

According to the present disclosure, the bottom surface of the foldable portion P1 of the substrate 102 is defined as a first bottom surface BS1, which is the bottom surface of the supporting film 1023 in this embodiment, and the bottom surface of the display structure 106 on the foldable portion P1 (which means in the foldable region 150 of the foldable display device 100) is defined as a second bottom surface BS2. It is noteworthy that the second bottom surface BS2 of the display structure 106 refers to the bottom surface of the driving element 1061. Therefore, in the top-gate type driving element 1061, the second bottom surface BS2 is the bottom surface of the semiconductor layer 1061C. In a variant embodiment, when the driving element is a bottom-gate type TFT, the second bottom surface BS2 is the bottom surface of the gate electrode of the driving element. In addition, the top surface of the protecting layer 108 in the foldable portion P1 is defined as a first top surface TS1, and the top surface of the display structure 106 on the foldable portion P1 (which means in the foldable region 150 of the foldable display device 100) is defined as a second top surface TS2. Since the display unit 1062 is disposed at the upper part of the display structure 106, the top surface of the second electrode 1062c is defined as the second top surface TS2.

According to the present disclosure, a first distance d1 is measured from the first bottom surface BS1 to the first top surface TS1, a second distance d2 is measured from the first bottom surface BS1 to the second bottom surface BS2, and the ratio of the second distance d2 to the first distance d1 (represented as a first ratio d2/d1) is in a range from 0.3 to 0.5. In addition, a third distance d3 is measured from the first bottom surface BS1 to the second top surface TS2, wherein the third distance d3 is greater than the second distance d2 and the ratio of the third distance d3 to the first distance d1 (represented as a second ratio a d3/d1) is in a range from 0.4 to 0.6.

Furthermore, the thickness of the foldable portion P1 of the substrate 102 is defined as a first thickness t1, the thickness of the protecting layer 108 on the foldable portion P1 is defined as a second thickness t2, and the ratio of the thickness t1 of the foldable portion P1 to the thickness t2 of the protecting layer 108 (represented as a third ratio t1/t2) is in a range from 0.4 to 1.3. In addition, a portion of the polarizer 1081 in the foldable region 150 of the foldable display device 100 (i.e., the portion of the polarizer 1081 disposed on the foldable portion P1) has a thickness t21, a portion of the cover layer 1082 in the foldable region 150 of the foldable display device 100 (i.e., the portion of the cover layer 108 disposed on the foldable portion P1) has a thickness t22, and the thickness t1 of the foldable portion P1 is greater than both the thickness t21 of the polarizer 1081 on the foldable portion P1 and the thickness t22 of the cover layer 1082 on the foldable portion P1. In some embodiments, the above relations of the thickness t1, the thickness t21, and the thickness t22 can optimize the stress distribution of the foldable display device 100 when it is folded.

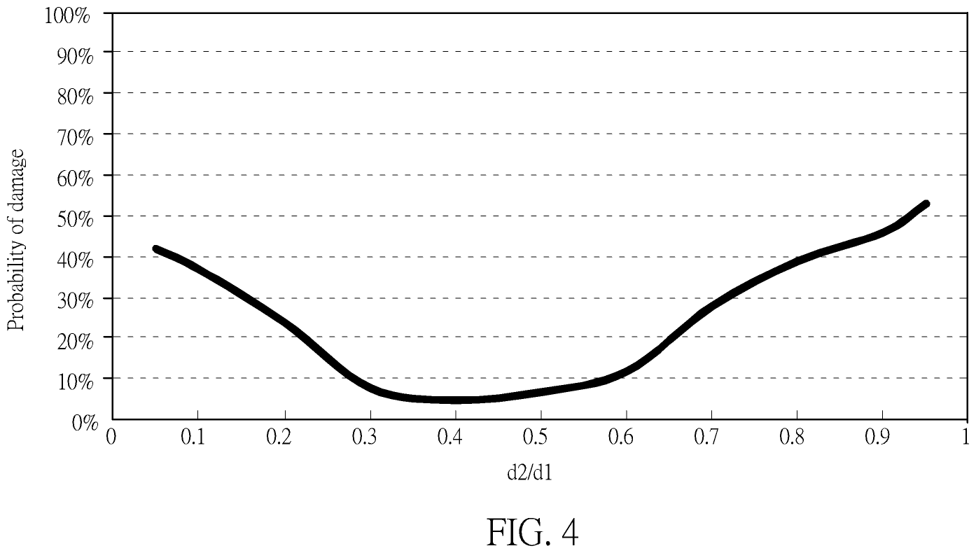

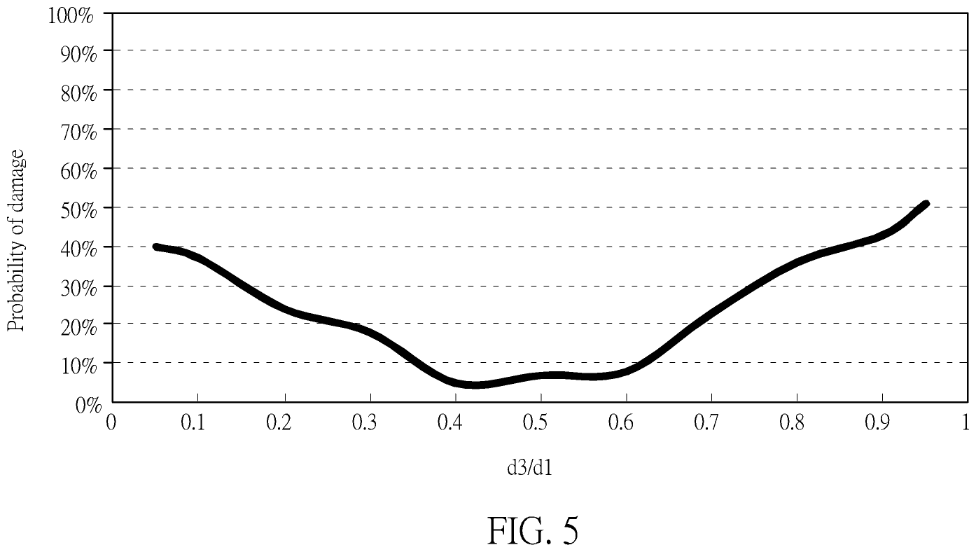

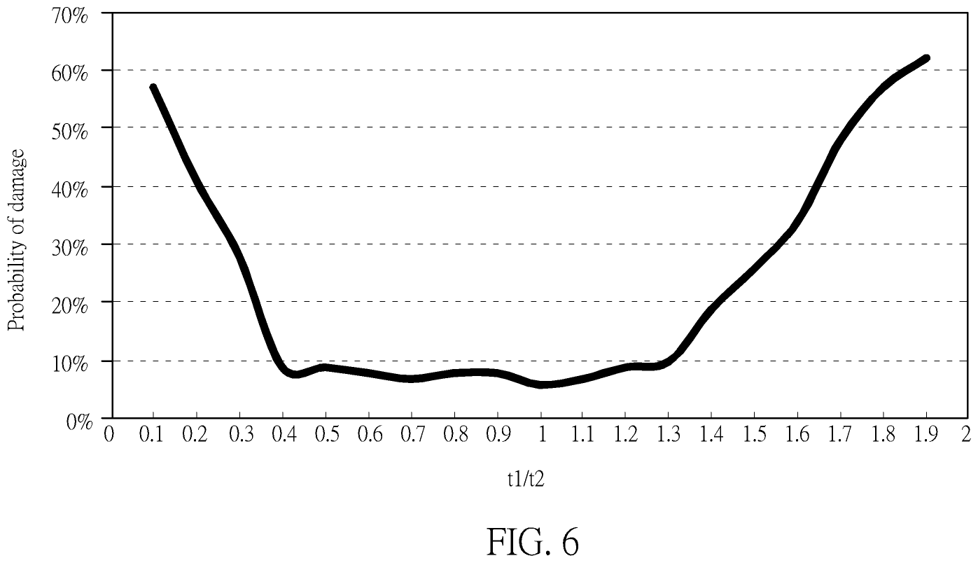

Referring to FIG. 4, FIG. 5, and FIG. 6, FIG. 4 is a schematic diagram illustrating the probability of damage versus different values of the first ratio d2/d1, FIG. 5 is a schematic diagram illustrating the probability of damage versus different values of the second ratio d3/d1, and FIG. 6 is a schematic diagram illustrating the probability of damage versus different values of the third ratio t1/t2. FIG. 4, FIG. 5, and FIG. 6 are test results by folding the foldable display device 100,000 times and then calculating the probability of damage under microscope observation. As shown in FIG. 4, when the first ratio d2/d1 of the foldable display device 100 is in a range from 0.3 to 0.5, the probability of damage is lower than 10%. As shown in FIG. 5, when the second ratio d3/d1 of the foldable display device 100 of the present disclosure is in a range from 0.4 to 0.6, the probability of damage is lower than 10%. Similarly, as shown in FIG. 6, when the third ratio t1/t2 of the foldable display device 100 of the present enclosure is in a range from 0.4 to 1.3, the probability of damage is lower than 10%. Accordingly, the structure of the foldable display device 100 of the present disclosure with the first ratio d2/d1, the second ratio d3/d1, or the third ratio t1/t2 that meets the above-mentioned ranges can have a good reliability, and the damage caused by concentration of stress during folding of the foldable display device 100 may be mitigated.

In addition, according to the present disclosure, the substrate 102 has a young's modulus, represented as Y1, the polarizer 1081 has a young's modulus, represented as Y2, and the cover layer 1082 has a young's modulus, represented as Y3. The foldable portion P1 of the substrate 102 has the thickness t1, the polarizer 1081 on the foldable portion P1 has a thickness t21, and the cover layer 1082 on the foldable portion P1 has a thickness t22. The values of Y1, Y2, Y3, t1, t21, and t22 conform to the equation: 0.75≤Y1*t1³/(Y2*t21³+Y3*t22³)≤1.25. In some embodiments, this relation between the young's modulus and the thickness may provide the foldable display device 100 with stress optimization, thus preventing the device from cracking when folded.

The foldable display device of the present disclosure is not limited to the above mentioned embodiment. Further embodiments or variant embodiments of the present disclosure are described below. It should be noted that the technical features in different embodiments described can be replaced, recombined, or mixed with one another to constitute another embodiment without departing from the spirit of the present disclosure. For making it easier to compare the difference between the embodiments and variant embodiments, the following description will detail the dissimilarities among different variant embodiments or embodiments and the identical features will not be redundantly described.

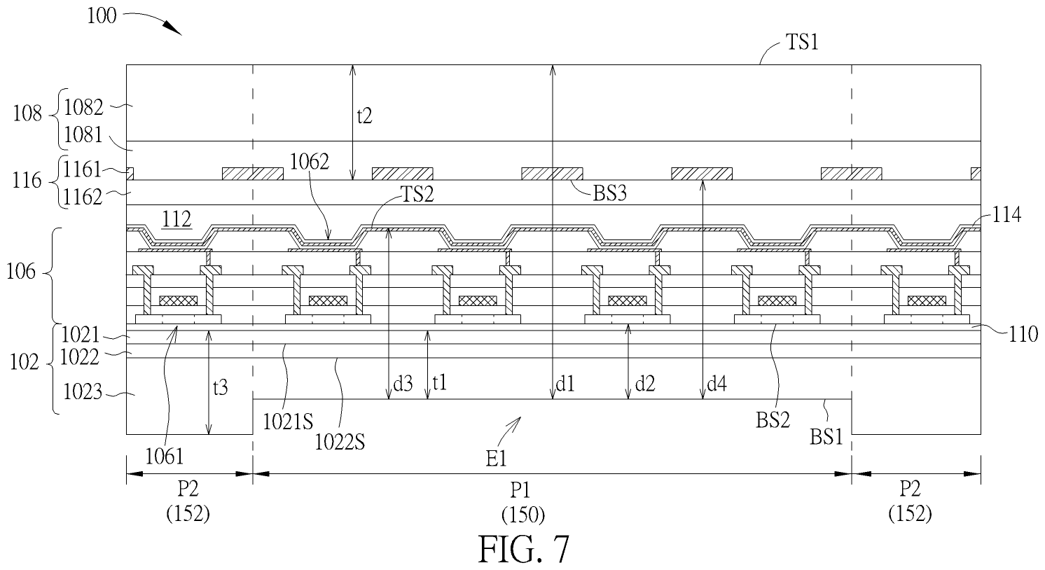

Referring to FIG. 7, FIG. 7 is a partial-enlargement schematic diagram illustrating a cross-section of a foldable display device according to a second embodiment of the present disclosure. The foldable display device 100 has two main regions 152 and a foldable region 150 disposed between the two main regions 152. FIG. 7 shows that the driving element 1061 of the display structure 106 has top-gate type TFT structure, but not limited thereto. The structure of the display structure 106 may be similar to the display structure 106 shown in FIG. 3. However, the display structure 106 of this embodiment and other embodiments of the present disclosure may have other arrangements and structures of electronic elements (such as with various number of TFTs and with identical or non-identical structures of TFTs), which will not be redundantly described in detail.

One of the differences between this embodiment shown in FIG. 7 and the first embodiment shown in FIG. 3 is that the foldable display device 100 has different thicknesses in different regions. Such thickness difference can be implemented by changing the thicknesses of the substrate 102 or the protecting layer 108 in different regions. Specifically, as shown in FIG. 7, the thickness t1 of the foldable portion P1 of the substrate 102 is less than the thickness t3 of the main portions P2 of the substrate 102 in this embodiment. For example, the supporting film 1023 of the substrate 102 has a recess E1 in the foldable portion P1. Thus, the thickness t1 of the foldable portion P1 is less than the thickness t3 of the other portions (the main portions P2). The recess E1 may be disposed in the whole foldable region 150, but not limited thereto. In some variant embodiments, the recess E1 can be disposed in only a part of the foldable region 150, but not in the whole foldable region 150. Although FIG. 7 only shows a cross-sectional view of a single recess E1, a plurality of recesses E1 can be disposed in the foldable region 150. In addition, as shown in FIG. 7, the recess E1 does not penetrate through the entire thickness of the supporting film 1023. Alternatively, in other embodiments (not shown), the recess E1 can penetrate through the entire thickness of the supporting film 1023, and expose the surface 1022s of the glue 1022 or expose the surface 1021s of the flexible substrate 1021. The relatively thin thickness of the substrate 102 in the foldable portion P1 can provide the foldable display device 100 a better flexibility and better stress optimization.

According to some embodiments, the foldable display device 100 can further include a touch structure. The touch layer in the touch structure can be attached on another flexible substrate, thus forming an out-cell touch structure. The touch layer can be disposed directly on the encapsulation layer 112, thus forming an on-cell touch structure. The touch layer can be integrated in the display structure 106, thus forming an in-cell touch structure. The touch structure hereinafter can include one touch layer or more than one touch layer.

FIG. 7 shows that the foldable display device 100 include an out-cell touch structure 116. The touch structure 116 is disposed on the foldable portion P1 and the main portion P2 and disposed between the protecting layer 108 and the display structure 106. The touch structure 116 includes a flexible substrate 1162 and a touch layer 1161 that includes a plurality of touch electrodes. The touch layer 1161 is formed on the flexible substrate 1162, and the flexible substrate 1162 may be attached on the encapsulation layer 112. The bottom surface of the touch layer 1161 is defined as a third bottom surface BS3, and the second top surface TS2 is disposed between the third bottom surface BS3 and the first bottom surface BS1. A fourth distance d4 is measured from the first bottom surface BS1 to the third bottom surface BS3. A ratio of the fourth distance d4 to the first distance d1 of the foldable display device 100 is defined as a fourth ratio d4/d1, and the fourth ratio d4/d1 is in a range from 0.5 to 0.7.

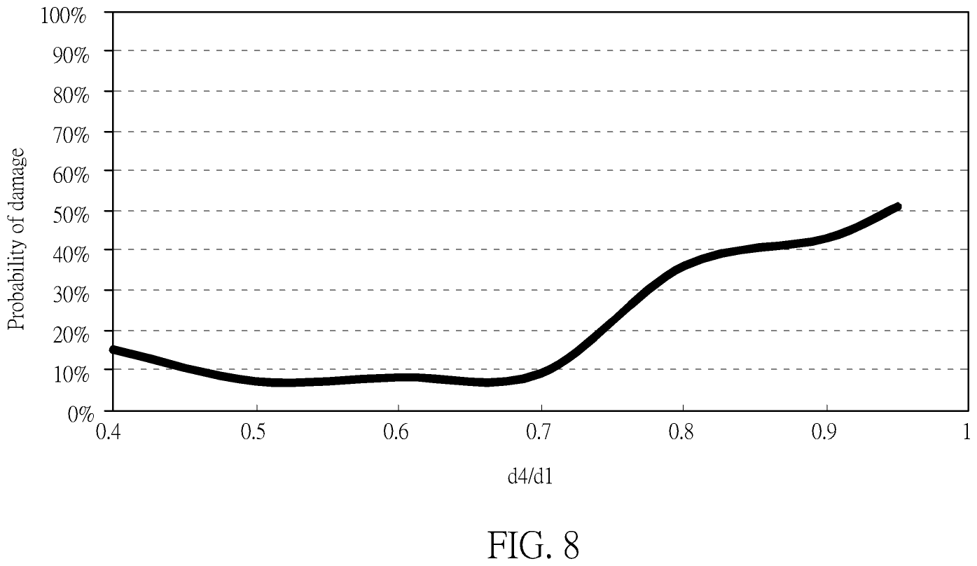

Referring to FIG. 8, FIG. 8 is a schematic diagram illustrating the probability of damage versus different values of the fourth ratio d4/d1 of the foldable display device. FIG. 8 illustrates the test results by folding the foldable display device 100,000 times and calculating the probability of damage under microscope observation. As shown in FIG. 8, when the foldable display device 100 has a structure with the fourth ratio d4/d1 in a range from 0.5 to 0.7, the probability of damage is lower than 10%. Therefore, the structure of the foldable display device 100 of this embodiment can provide an improved reliability for that the damage caused by stress concentration during folding may be mitigated.

It should be noted that, the foldable display device 100 in this embodiment may also meet at least one of the relations that the first ratio d2/d1 is in a range from 0.3 to 0.5, the second ration d3/d1 is in a range from 0.4 to 0.6, and the third ratio t1/t2 is in a range from 0.4 to 1.3, as mentioned in the first embodiment. Accordingly, the probability of damage resulted from folding of the foldable display device 100 can be lower than 10%. The structure of the foldable display device 100 introduced in the following embodiments may also have the same conditions of the first ratio d2/d1, the second ratio d3/d1, and the third ratio t1/t2, which will not be redundantly described in detail.

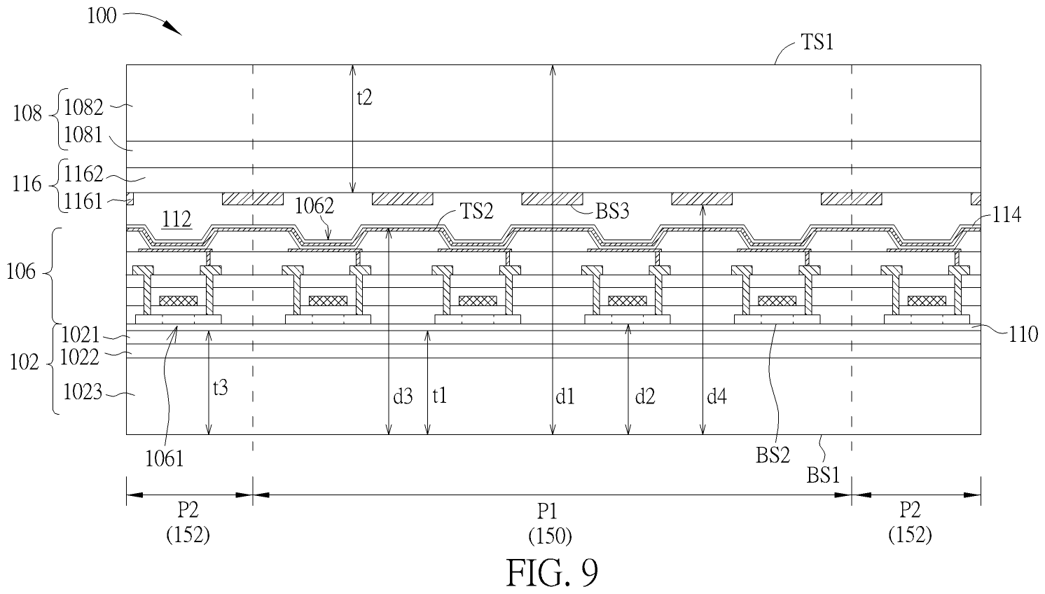

Referring to FIG. 9, FIG. 9 is a partial-enlargement schematic diagram illustrating a cross-section of a foldable display device according to a variant embodiment of the second embodiment of the present disclosure. The foldable display device 100 has two main regions 152, and a foldable region 150 disposed between the two main regions 152. As shown in FIG. 9, the structure of this variant embodiment is different from the second embodiment shown in FIG. 7 in that the thickness t1 of the foldable portion P1 is equal to the thickness t3 of the main portion P2, which means that the substrate 102 may have a flat bottom surface and may have no recess in the foldable portion P1. Furthermore, the foldable display device 100 of FIG. 9 includes an out cell touch structure 116, including the flexible substrate 1162 and the touch layer 1161. The touch layer 1161 is disposed on the lower side of the flexible substrate 1162 in this variant embodiment. In other words, the touch layer 1161 is disposed between the flexible substrate 1162 and the encapsulation layer 112. Thus, the fourth distance d4 measured from the first bottom surface BS1 to the third bottom surface BS3 of this variant embodiment may be less than the fourth distance d4 of the second embodiment. However, the fourth ratio d4/d1 of this variant embodiment may be still in the range from 0.5 to 0.7.

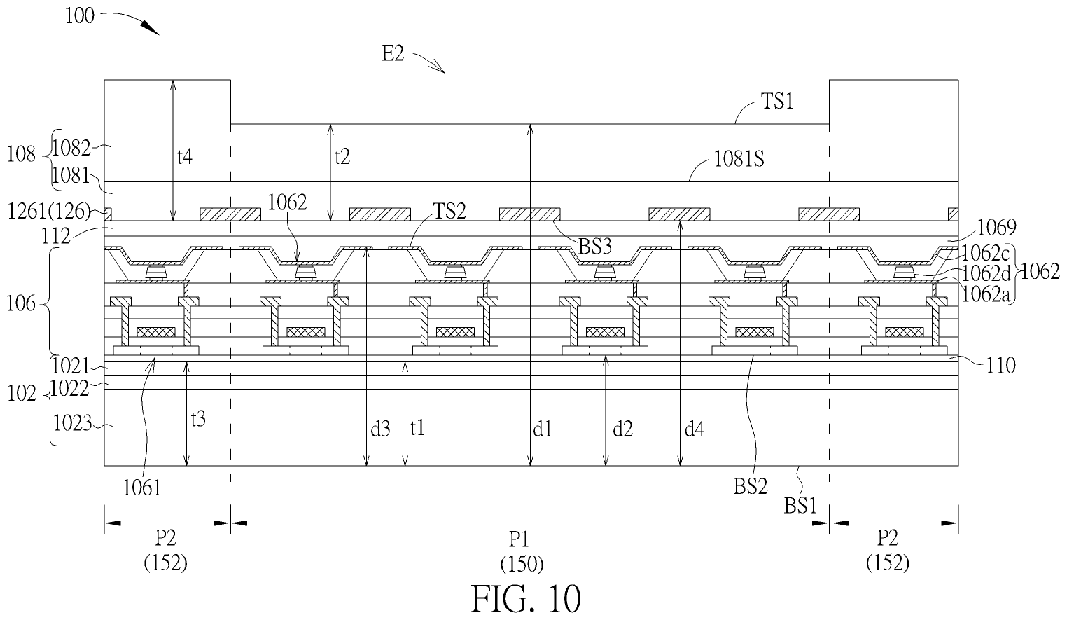

Referring to FIG. 10, FIG. 10 is a partial-enlargement schematic diagram illustrating a cross-section of a foldable display device according to a third embodiment of the present disclosure. The foldable display device 100 has two main regions 152, and a foldable region 150 disposed between the two main regions 152. In this embodiment, the foldable display device 100 has different thicknesses in the foldable region 150 and the main regions 152. Such difference can be implemented by changing the thickness of the protecting layer 108 in these two regions. As shown in FIG. 10, different from the second embodiment in FIG. 7, the protecting layer 108 in the foldable region 150 (on the foldable portion P1) has a thickness t2 less than the thickness t4 of the protecting layer 108 in the main region 152 (on the main portion P2) in this embodiment. In detail, the cover layer 1082 has a recess E2 in the foldable region 150 for instance. The recess E2 may be disposed in the whole foldable region 150, but not limited thereto. In some variant embodiments, the recess E2 can be disposed in only a part of the foldable region 150, but not in the whole foldable region 150. Although FIG. 10 only shows a cross-sectional view of a single recess E2, a plurality of recesses E2 can be disposed in the foldable region 150. Since the protecting layer 108 on the foldable portion P1 has a thinner thickness t2 in this embodiment, the third ratio t1/t2 may be greater than that of the foldable display device 100 shown in FIG. 9. As shown in FIG. 10, the recess E2 does not penetrate through the entire thickness of the cover layer 1082. Alternatively, in other embodiments (not shown), the recess E2 can penetrate through the entire thickness of the cover layer 1082, and expose the surface 1081s of the polarizer 1081.

Still referring to FIG. 10, in addition, the display unit 1062 includes a micro-LED structure, wherein a micro light emitting element 1062d (micro-LED) is disposed between the first electrode 1062a and the second electrode 1062c. Moreover, a quantum dot layer 1069 can be optionally disposed on the second electrode 1062c, so as to modulate the wavelength of the light emitted from the light emitting element 1062d. For example, the light emitting element 1062d may produce light with wavelength in a specific range (such as with a short wavelength), and the quantum dot layer 1069 may convert the light produced by the light emitting element 1062d into the light with wavelength in another range (such as with longer wavelength), so as to produce different colors of light. In some variant embodiments, the light emitting elements 1062d may directly produce different color light, and the quantum dot layer 1069 may be omitted. Furthermore, the foldable display device 100 of this embodiment includes an on-cell touch structure 126. The touch layer 1261 in this embodiment can be directly formed on the encapsulation layer 112 and the touch structure 126 does not include the flexible substrate 1162 shown in FIG. 7.

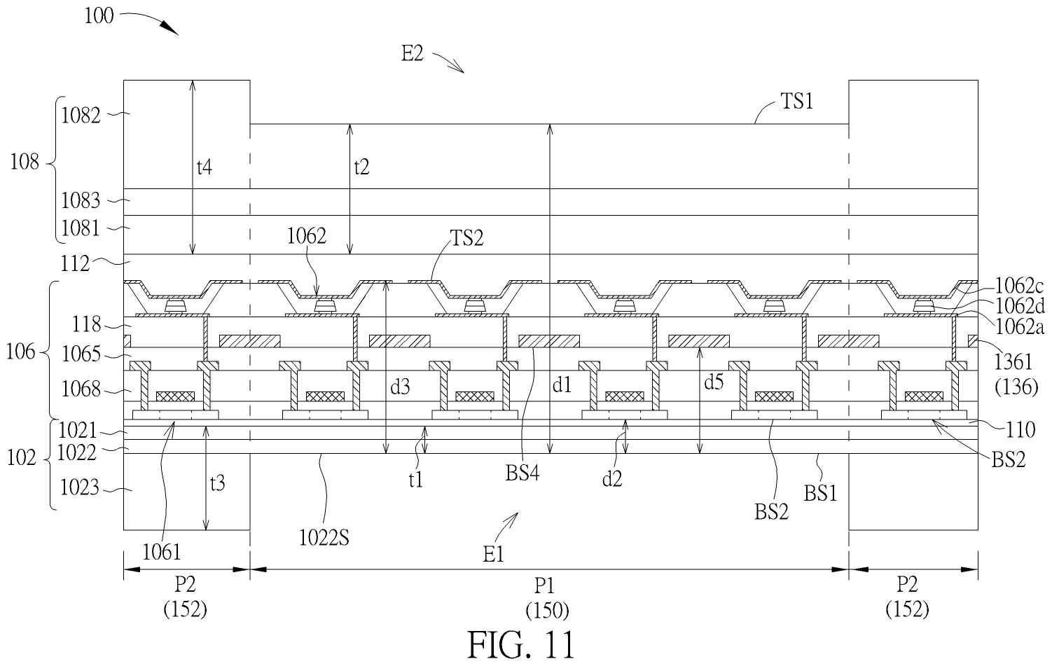

Referring to FIG. 11, FIG. 11 is a partial-enlargement schematic diagram illustration a cross-section of the foldable display device according to a fourth embodiment of the present disclosure. The foldable display device 100 has two main regions 152, and a foldable region 150 disposed between the two main regions 152. Different from the third embodiment shown in FIG. 10, the structure of the foldable display device 100 of this embodiment has a recess E1 on the lower side of the substrate 102 in the foldable portion P1 and has a recess E2 on upper side of the protecting layer 108 on the foldable portion P1. The substrate 102 of this embodiment is different from the substrate 102 in FIG. 7 in that the recess E1 penetrates through the entire thickness of the supporting film 1023 to expose the surface 1022s of the glue 1022. Therefore, a total thickness of the foldable display device 100 corresponding to the main portion P2 is greater than a total thickness of the foldable display device 100 corresponding to the foldable portion P1. As a result, the first distance d1 may be relatively smaller than the previous embodiments. The total thickness of the foldable display device 100 corresponding to the foldable portion P1 may be adjusted and decreased for optimizing the stress distribution during folding of the foldable display device 100.

Still referring to FIG. 11, compared with the display structure and touch layer of the third embodiment shown in FIG. 10, the foldable display device 100 shown in FIG. 11 may have an in-cell touch structure, also referred to as a touch in display (TID) structure. That is, the touch structure 136 may be integrated into the display structure 106. For example, the touch layer 1361 including a plurality of touch electrodes is disposed between the driving elements 1061 and the display units 1062. In this embodiment, the touch layer 1361 is disposed on the dielectric layer 1065 or on the dielectric layer 1068 and under the first electrodes 1062a, and a dielectric layer 118 is disposed between the first electrodes 1062 and the touch layer 1361. The bottom surface of the touch layer 1361 in this embodiment is defined as a fourth bottom surface BS4 that is between the second top surface TS2 of the display structure 106 and the second bottom surface BS2, and a fifth distance d5 is measured from the first bottom surface BS1 to the fourth bottom surface BS4. The ratio of the fifth distance d5 to the first distance d1 is defined as a fifth ratio d5/d1 which is in a range from 0.3 to 0.5. This ratio between the fifth distance d5 and the first distance d1 can provide an improved stress distribution during the folding of the foldable display device 100, so as to decrease the probability of damage and improve the reliability of the foldable display device 100. Furthermore, the encapsulation layer 112 can be directly disposed on the display structure 106, and the protecting layer 108 can be disposed on the encapsulation layer 112. The display structure 106 in FIG. 11 may not include the quantum dot layer 1069 shown in FIG. 10. The protecting layer 108 can further include an optical clear adhesive layer 1083 disposed between the polarizer 1081 and the cover layer 1082.

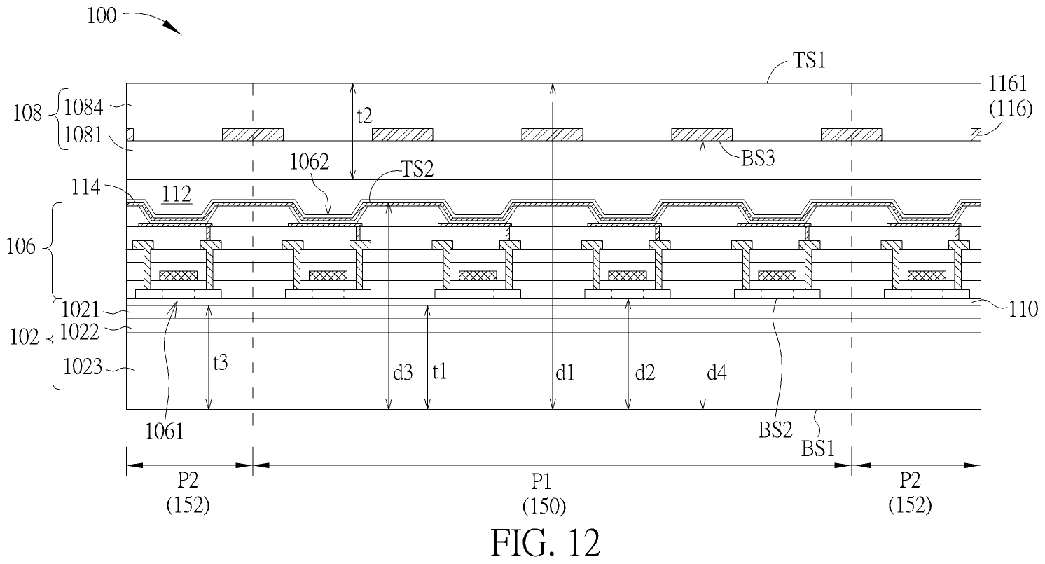

Referring to FIG. 12, FIG. 12 is a partial-enlargement schematic diagram illustration a cross-section of the foldable display device according to a fifth embodiment of the present disclosure. The foldable display device 100 of FIG. 12 includes an out-cell touch structure. Compared with the display structure of the second embodiment shown in FIG. 7, the flexible substrate 1162 is omitted in this embodiment. As shown in FIG .12, the touch layer 1161 may be disposed on the polarizer 1081 in the protecting layer 108, which means that the polarizer 1081 replaces the flexible substrate 1162 of the touch structure 116, and the touch structure 116 is integrated to the polarizer 1081. In a variant embodiment, the touch layer 1161 formed on the polarizer 1081 may be disposed between the polarizer 1081 and the encapsulation layer 112. Still, according to the present disclosure, the fourth ratio d4/d1 (the ratio of the fourth distance d4 between the first bottom surface BS1 and the third bottom surface BS3 of the touch layer 1161 to the first distance d1 between the first top surface TS1 and the first bottom surface BS1) is in the range from 0.5 to 0.7. Since the flexible substrate 1162 of the touch structure 116 is omitted, and the touch layer 116 is integrated in the protecting layer 108, the whole thickness of the foldable display device 100 may be decreased. In addition, the cover layer 1082 in the previous embodiments is replaced by a hard coating cover layer 1084. The hard coating cover layer 1084 may be scratching resistant and include polymer material, which may be formed through a coating process and an optical curing process for example. In another variant embodiment, the hard coating cover layer 1084 may be replaced by a thin glass. The thickness of the hard coating cover layer 1084 or the thin glass may be less than 100 μm, such as in a range from 50 μm to 100 μm, but not limited thereto.

According to the present disclosure, the foldable display device includes a substrate, a display structure, a protecting layer, and an optional touch layer. The relative thickness ratio and relative distance ratio of the layers or structures of the foldable portion have specific values. The first ratio d2/d1 is in the range from 0.3 to 0.5. Optionally, the second ratio d3/d1 is in the range from 0.4 to 0.6, and the third ratio t1/t2 is in the range from 0.4 to 1.3. In a further optional situation, the fourth ratio d4/d1 is in the range from 0.5 to 0.7, or the fifth ratio d5/d1 is in the range from 0.3 to 0.5. The present disclosure provides the ranges of the positions of the top electrode (the second electrode) of the light emitting unit and the active layer or gate electrode layer of the TFTs in the whole structure. Under such circumstances, the stress distribution during folding of the foldable display device can be optimized. In other words, the structure that meets the above-mentioned condition has less stress so as to reduce damage probability of the elements of the foldable display device, especially the TFTs, the electrodes, and the touch layer.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A foldable display device, comprising:
a substrate including a foldable portion, wherein the foldable portion has a plurality of recesses, and the foldable portion has a first bottom surface at one of the recesses;
a display structure disposed on the foldable portion and having a second bottom surface, wherein the display structure has a plurality of display units;
an encapsulation layer disposed on the display structure;
a touch layer disposed on the encapsulation layer, wherein the encapsulation layer is disposed between the display structure and the touch layer, and at least a portion of the touch layer and one of the display units adjacent to the at least a portion of the touch layer are not overlapped in a thickness direction; and
a protecting layer disposed on the foldable portion and on the touch layer, the protecting layer having a first top surface;
wherein a first distance is measured from the first bottom surface to the first top surface, a second distance is measured from the first bottom surface to the second bottom surface, and a ratio of the second distance to the first distance is in a range from 0.3 to 0.5.

2. The foldable display device as claimed in claim 1, wherein the display structure has a second top surface, a third distance is measured from the first bottom surface to the second top surface, a ratio of the third distance to the first distance is in a range from 0.4 to 0.6, and the third distance is greater than the second distance.

3. The foldable display device as claimed in claim 1, wherein the touch layer has a third bottom surface, a fourth distance is measured from the first bottom surface to the third bottom surface, and a ratio of the fourth distance to the first distance is in a range from 0.5 to 0.7.

4. The foldable display device as claimed in claim 1, wherein the touch layer has a third bottom surface, a fourth distance is measured from the first bottom surface to the third bottom surface, and a ratio of the fourth distance to the first distance is in a range from 0.3 to 0.5.

5. The foldable display device as claimed in claim 1, wherein a ratio of a thickness of the foldable portion of the substrate to a thickness of the protecting layer on the foldable portion is in a range from 0.4 to 1.3.

6. The foldable display device as claimed in claim 1, wherein the substrate further includes a main portion adjoining to the foldable portion, and a thickness of the main portion of the substrate is greater than a thickness of the foldable portion of the substrate.

7. The foldable display device as claimed in claim 1, wherein the substrate further includes a main portion adjoining to the foldable portion, a total thickness of the foldable display device corresponding to the main portion is greater than a total thickness of the foldable display device corresponding to the foldable portion.

8. The foldable display device as claimed in claim 1, wherein the protecting layer comprises a polarizer and a cover layer, and a thickness of the foldable portion is greater than a thickness of the polarizer on the foldable portion.
